(19) United States
(12) Patent Application Publication
(10) Pub. No.: US 2021/0320158 A1
(43) Pub. Date: Oct. 14, 2021

(54) DISPLAY DEVICE AND SEMICONDUCTOR DEVICE

(71) Applicant: Japan Display Inc., Tokyo (JP)

(72) Inventors: Akihiro HANADA, Tokyo (JP); Toshihide JINNAI, Tokyo (JP); Isao SUZUMURA, Tokyo (JP); Hajime WATAKABE, Tokyo (JP); Ryo ONODERA, Tokyo (JP)

(73) Assignee: Japan Display Inc., Tokyo (JP)

(21) Appl. No.: 17/304,569

(22) Filed: Jun. 23, 2021

Related U.S. Application Data
(63) Continuation of application No. PCT/JP2019/049263, filed on Dec. 17, 2019.

(30) Foreign Application Priority Data
Dec. 26, 2018 (JP) 2018-241933

(51) Int. Cl. H01L 27/32; G02F 1/1333

(52) U.S. Cl. CPC H01L 27/3227; G02F 1/13338; H01L 27/3262

(57) ABSTRACT

The purpose of the present invention is to increase ON current of the oxide semiconductor thin film transistor. An example of the structure that attains the purpose is:
a display device having a substrate and a thin film transistor of an oxide semiconductor formed on the substrate including:
a thickness of a source region and a drain region is thicker than a thickness of a channel region of the oxide semiconductor,
the channel region has projections at portions contacting the source region and the drain region,
a thickness of the projection is thicker than a thickness of the center of the channel region, and
a thickness of the projection is thicker than a thickness of the source region and the drain region.

The present application is a continuation application of International Application No. PCT/JP2019/049263, filed on Dec. 17, 2019, which claims priority to Japanese Patent Application No. 2018-241933, filed on Dec. 26, 2018. The contents of these applications are incorporated herein by reference in their entirety.

### BACKGROUND OF THE INVENTION

### (1) Field of the Invention

The present invention relates to display devices and semiconductor devices having TFTs in which gate voltage—drain current characteristic is improved.

The liquid crystal display device has a structure configured such that the TFT substrate, in which the pixels, having the pixel electrodes and the TFTs (Thin Film Transistors), are arranged in matrix, and the counter substrate, in which black matrix and so forth are formed, oppose to each other; and the liquid crystal is sandwiched there between. The images are formed by controlling the light transmittance in the liquid crystal in each of the pixels. On the other hand, the organic EL display device has a light emitting layer in each of the pixels; the color images are formed by controlling the light emitted from each of the organic light emitting layers with the TFTs. The organic EL display device does not need a back light, thus it is advantageous for a display device to be made thinner.

The polysilicon semiconductor has high mobility, thus, it is suitable for the TFTs for driving circuits. On the other hand, the oxide semiconductor has high OFF resistance which gives low OFF current, thus it is suitable for the switching TFTs in the pixels. The oxide semiconductor TFTs, however, have a problem that deviations in characteristics are large.

Patent document 1 discloses the channel being made two layers to decrease the deviation in characteristics in oxide semiconductor TFTs.

Patent document 1: Japanese patent No. 5503667

### SUMMARY OF THE INVENTION

On and Off of the TFT are controlled by gate voltage. The oxide semiconductor TFT has lower OFF current compared with the polysilicon semiconductor TFT; however, the oxide semiconductor TFT has a task to increase ON current.

The purpose of the present invention is to increase ON current with low OFF current maintained specifically in the oxide semiconductor TFT, thus to realize display devices or semiconductor devices having high response characteristics.

The present invention solves the above explained problems; the concrete measures are as follows.

(1) A display device having a substrate and a thin film transistor of an oxide semiconductor formed on the substrate including:

a thickness of a source region and a drain region is thicker than a thickness of a channel region of the oxide semiconductor,

the channel region has projections at portions contacting the source region and the drain region,

a thickness of the projection is thicker than a thickness of the center of the channel region, and

a thickness of the projection is thicker than a thickness of the source region and the drain region.

(2) A semiconductor device having a substrate and a sensor element formed on the substrate including:

the sensor element has a thin film transistor of an oxide semiconductor,

a thickness of a part of a channel region is thinner than a thickness of a source region and a drain region in the oxide semiconductor,

the channel region has projections at portions contacting the source region and the drain region,

a thickness of the projection is thicker than a thickness of the center of the channel region, and

a thickness of the projection is thicker than a thickness of the source region and the drain region.

### BRIEF DESCRIPTION OF THE DRAWINGS

FIG. 1 is a plan view of a liquid crystal display device;

FIG. 2 is a plan view of a display area of the liquid crystal display device;

FIG. 3 is a cross sectional view of the display area of the liquid crystal display device;

FIG. 4 is a detailed cross sectional view of FIG. 3 in the vicinity of a TFT;

FIG. 5 is an example of cross sectional view of conventional TFT;

FIG. 6 is another example of cross sectional view of conventional TFT;

FIG. 7 is a graph of a relation between the gate voltage and the drain current when the SD resistance is relatively low;

FIG. 8 is a graph of a relation between the gate voltage and the drain current when the SD resistance is relatively high;

FIG. 9 is a graph of a relation between a thickness of the oxide semiconductor and a sheet resistance of the oxide semiconductor;

FIG. 10A is a cross sectional view of top gate type oxide semiconductor TFT;

FIG. 10B is a plan view of top gate type oxide semiconductor TFT;

FIG. 11A is a cross sectional view of top gate type oxide semiconductor TFT of another example;

FIG. 11B is a plan view of top gate type oxide semiconductor TFT of another example;

FIG. 12A is a cross sectional view of top gate type oxide semiconductor TFT in which the light shading film is disposed;

FIG. 12B is a plan view of top gate type oxide semiconductor TFT in which the light shading film is disposed;

FIG. 13A is a cross sectional view of another example of top gate type oxide semiconductor TFT in which the light shading film is disposed;

FIG. 13B is a plan view of another example of top gate type oxide semiconductor TFT in which the light shading film is disposed;

FIG. 14A is a cross sectional view of bottom gate type oxide semiconductor TFT;

FIG. 14B is a plan view of bottom gate type oxide semiconductor TFT;

FIG. 15A is a cross sectional view of dual gate type oxide semiconductor TFT;

FIG. 15B is a plan view of dual gate type oxide semiconductor TFT;

FIG. 16A is a cross sectional view in which the oxide semiconductor is formed on the undercoat layer in a process for manufacturing the oxide semiconductor of the present invention;

FIG. 16B is a process following FIG. 16A;

FIG. 16C is a process following FIG. 16B;

FIG. 16D is a process following FIG. 16C;

FIG. 16E is a process following FIG. 16D;

FIG. 16F is a process following FIG. 16E;

FIG. 16G is a process following FIG. 16F;

FIG. 17A is a cross sectional view in which the oxide semiconductor is formed on the undercoat layer in another process for manufacturing the oxide semiconductor of the present invention;

FIG. 17B is a process following FIG. 17A;

FIG. 17C is a process following FIG. 17B;

FIG. 17D is a process following FIG. 17C;

FIG. 17E is a process following FIG. 17D;

FIG. 17F is a process following FIG. 17E;

FIG. 17G is a process following FIG. 17F;

FIG. 17H is a process following FIG. 17G;

FIG. 18A is a cross sectional view in which the oxide semiconductor is formed on the undercoat layer in yet another process for manufacturing the oxide semiconductor of the present invention;

FIG. 18B is a process following FIG. 18A;

FIG. 18C is a process following FIG. 18B;

FIG. 18D is a process following FIG. 18C;

FIG. 18E is a process following FIG. 18D;

FIG. 18F is a process following FIG. 18E;

FIG. 19 is a cross sectional view of the display area of the organic EL display device;

FIG. 20 is a cross sectional view of detecting an area of the photo sensor device; and

FIG. 21 is a plan view of the photo sensor device.

### DETAILED DESCRIPTION OF THE PREFERRED EMBODIMENTS

The present invention is explained in the following embodiments in detail.

### Embodiment 1

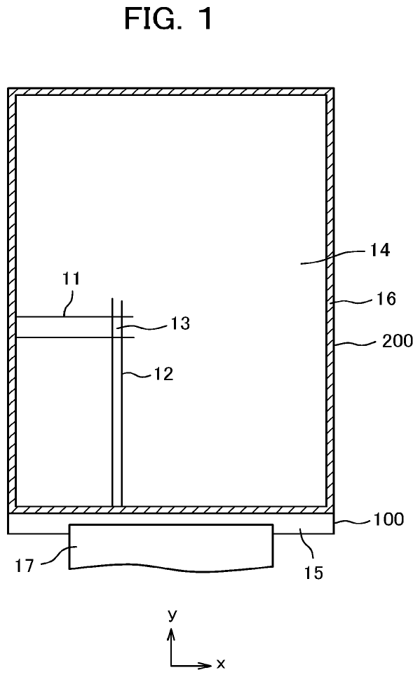

FIG. 1 is a plan view of the liquid crystal display device, to which the present invention is applied. In FIG. 1, the TFT substrate 100 and the counter substrate 200 are adhered to each other by the seal material 16; liquid crystal is sandwiched between the TFT substrate 100 and the counter substrate 200. The display area 14 is formed in an area where the TFT substrate 100 and the counter substrate 200 overlap each other.

The scan lines 11 extend in lateral direction (x direction) and are arranged in longitudinal direction (y direction); the video signal lines 12 extend in longitudinal direction and are arranged in lateral direction in the display area 14 of the TFT substrate 100. The pixel 13 is formed in an area surrounded by the scan lines 11 and the video signal lines 12. The TFT substrate 100 is made larger than the counter substrate 200; the terminal area 15 is formed in the area that the TFT substrate 100 does not overlap the counter substrate 200. The flexible wiring substrate 17 connects to the terminal area 15; the driver IC that drives the liquid crystal display device is installed on the flexible wiring substrate 17.

Since the liquid crystal is not self-luminous, a back light is set at the rear of the TFT substrate 100. The liquid crystal generates pictures by controlling the light transmission through each of the pixels. The flexible wiring substrate 17 is bent back to the rear of the back light, thus, overall size of the liquid crystal display device is made compact.

The TFT of the oxide semiconductor, which has low leak current, is used in the display area 14 in the liquid crystal display device according to the present invention. The scan line driving circuit, for example, is formed in the peripheral area in the vicinity of the seal material 16. The TFT of the polysilicon semiconductor, which has a high carrier mobility, is mainly used in the scan line driving circuit; however, the TFT of the oxide semiconductor can also be used in the driving circuit.

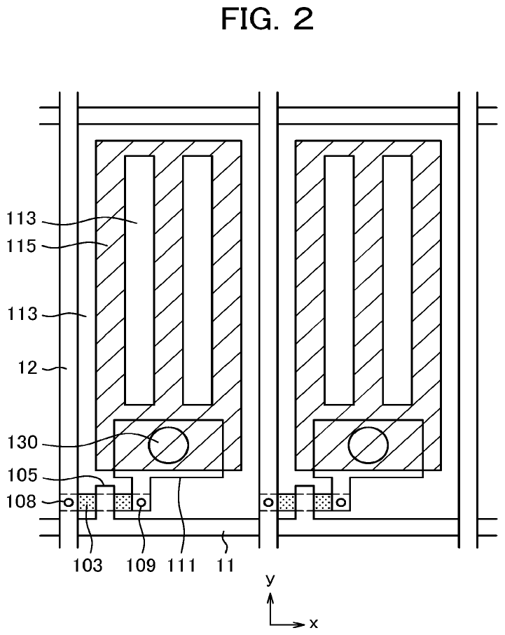

FIG. 2 is a plan view of the pixel 13 in the display area 14. FIG. 2 is a structure of FFS (Fringe Field Switching) mode of the IPS (In Plane Switching) liquid crystal display device. The TFT in figure uses the oxide semiconductor film 103. The TFT of the oxide semiconductor has low leak current, thus, it is suitable for the switching TFT.

In FIG. 2, the scan lines 11 extend in lateral direction (x direction) and are arranged in longitudinal direction (y direction); the video signal lines 12 extend in longitudinal direction and are arranged in lateral direction. The pixel electrode 115 is formed in the area surrounded by the scan lines 11 and the video signal lines 12. In FIG. 2, the oxide semiconductor TFT using the oxide semiconductor film 103 is formed between the video signal line 12 and the pixel electrode 115. In the oxide semiconductor TFT, the video signal line 12 constitutes the drain electrode, a branch from the scan line 11 constitutes the gate electrode 105. The source electrode 111 of the oxide semiconductor TFT extends toward the pixel electrode 115 and connects with the pixel electrode 115 via through hole 130.

The pixel electrode 115 is formed like comb shaped. The common electrode 113 is formed in a planar shape under the pixel electrode 115 via the capacitance insulating film. The common electrode 113 is formed continuously common to plural pixels. When a video signal is applied to the pixel electrode 115, lines of forces are generated between the pixel electrode 115 and the common electrode 113 through the liquid crystal layer to rotate the liquid crystal molecules, consequently, pictures are formed. In FIG. 2, the light shading film (light shield electrode), which is formed between the TFT and the substrate, is omitted.

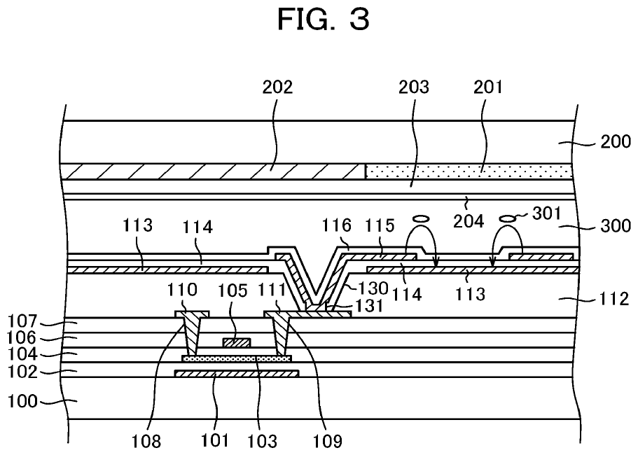

FIG. 3 is a cross sectional view of the liquid crystal display device corresponding to FIG. 2. In FIG. 3, the TFT of the oxide semiconductor 103 is used. The oxide semiconductor TFT is suitable for the switching TFT because of its low leak current.

Examples of the oxide semiconductors are indium gallium zinc oxide (IGZO), indium tin zinc oxide (ITZO), zinc oxide nitride (ZnON), indium gallium oxide (IGO), and so forth. In this embodiment, the IGZO is used for the oxide semiconductor.

In FIG. 3, the light shading film 101 made of metal is formed on the TFT substrate 100, which is made of glass or resin like e.g. polyimide. The metal can be the same metal for e.g. the gate electrode 105, which is formed later. The light shading film 101 is to block the light from the back light for the channel of the TFT, which is formed later.

Another important role of the light shading film 101 is to prevent the oxide semiconductor TFT from being influenced by electric charges accumulated in the substrate 100. Specifically, when the substrate 100 is formed from resin such as polyimide, which easily accumulates electric charges, the TFT strongly influenced by the electric charges in the substrate 100. Applying a certain voltage to the light shield film 101 can prevent the TFT from being influenced by the electric charges accumulated in the substrate 100.

The undercoat film 102 is formed covering the light shading film 101. The undercoat film 102 prevents the oxide semiconductor film 103 from being contaminated by impurities from the TFT substrate 100. The undercoat film 102 is often formed from a laminated film of a silicon oxide (represented by SiO) film and a silicon nitride (represented by SiN) film. Sometimes, an aluminum oxide (represented by A10) film may be further laminated as the undercoat film 102.

In FIG. 3, the oxide semiconductor film 103 that constitutes the TFT is formed on the undercoat film 102. A thickness of the semiconductor film 103 is 10 to 100 nm. The gate insulating film 104 is formed from SiO covering the oxide semiconductor film 103. The gate insulating film 104, which is formed from SiO, supplies oxygen to the oxide semiconductor film 103 to stabilize the characteristics of the channel. The gate electrode 105 is formed on the gate insulating film 104.

The interlayer insulating film 106 is formed from e.g. SiO covering the gate electrode 105. A thickness of the interlayer insulating film 106 is e.g. 150 to 300 nm. The inorganic passivation film 107 is formed from e.g. SiN on the interlayer insulating film 106. A thickness of the inorganic passivation film 107 is e.g. 100 to 200 nm.

Through holes 108 and 109 are formed penetrating the inorganic passivation film 107, the interlayer insulating film 106 and the gate insulating film 104 to connect the drain electrode 110 with the oxide semiconductor film 103 and to connect the source electrode 111 with the oxide semiconductor film 103. In FIG. 3, the video signal line 12 works as the drain electrode 110, and the source electrode 111 connects to the pixel electrode 115 via the through holes 130 and 131.

In FIG. 3, the organic passivation film 112 is formed covering the drain electrode 110 and the source electrode 111. The organic passivation film 112 is formed from e.g. acrylic resin. Since organic passivation film 112 has a role as a flattening film and a role to decrease a floating capacitance between the video signal line 12 and the common electrode 113, it is made thick as 2 to 4 microns. The through hole 130 is formed in the organic passivation film 112 to connect the source electrodes 111 with the pixel electrode 115.

The common electrode 113, which is formed from transparent conductive film of e.g. ITO (Indium Tin Oxide), is formed on the organic passivation film 112. The common electrode 113 is formed in a planar shape in common to plural pixels. The capacitance insulating film 114, made of SiN, is formed on the common electrode 113. The pixel electrode 115, which is formed from transparent conductive film of e.g. ITO, is formed on the capacitance insulating film 114. The pixel electrode 115 is formed comb like shape. The capacitance insulating film 114, sandwiched between the pixel electrode 115 and the common electrode 113, forms a pixel capacitance.

The alignment film 116 is formed covering the pixel electrode 115. The alignment film 116 controls the initial alignment of the liquid crystal molecules 301. The alignment treatment for the alignment film 116 is conducted either by rubbing process or optical alignment process. Since IPS does not need a pre-tilt angle, optical alignment is suitable.

In FIG. 3, the counter substrate 200 is formed opposing to the TFT substrate 100 sandwiching the liquid crystal layer 300. The color filter 201 and the black matrix 202 are formed on the counter substrate 200; the overcoat film 203 is formed covering the color filter 201 and the black matrix 202. The alignment film 204 is formed on the overcoat film 203. The alignment treatment for the alignment film 204 is the same as for the alignment film 116 of the TFT substrate 100.

In FIG. 3, when a voltage is applied between the common electrode 113 and the pixel electrode 115, lines of forces as depicted in FIG. 3 are generated to rotate the liquid crystal molecules 301, consequently, a transmittance in the pixel is controlled. Pictures are formed by controlling transmittance of light in each of the pixels.

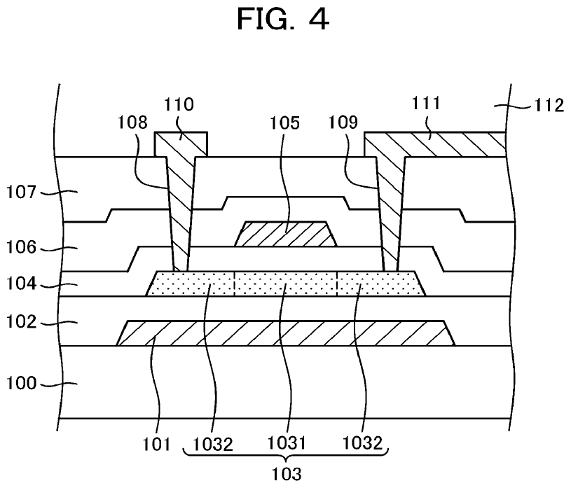

FIG. 4 is a cross sectional view that shows detailed structure in the vicinity of the TFT in FIG. 3. In FIG. 4, the oxide semiconductor 103 is divided into the channel region 1031, which is beneath the gate electrode 105, and the drain region 1032 and the source region 1032, which are located at both sides of the channel region 1031. Herein after the drain region and the source region may be referred to as the SD region 1032. The channel region 1031 controls ON or OFF of the TFT; the SD region 1032 gets conductivity through e.g. ion implantation.

As shown in FIG. 4, the drain electrode 110 and the source electrode 111 connect to the oxide semiconductor 103 through the through holes 108 and 109 formed in the inorganic passivation film 107, the interlayer insulating film 106, and the gate insulating film 104. In the figures herein after, the interlayer insulating film 106, the inorganic passivation film 107, the through holes 108 and 109, the drain electrode 110 and the source electrode 111 are omitted to avoid complication.

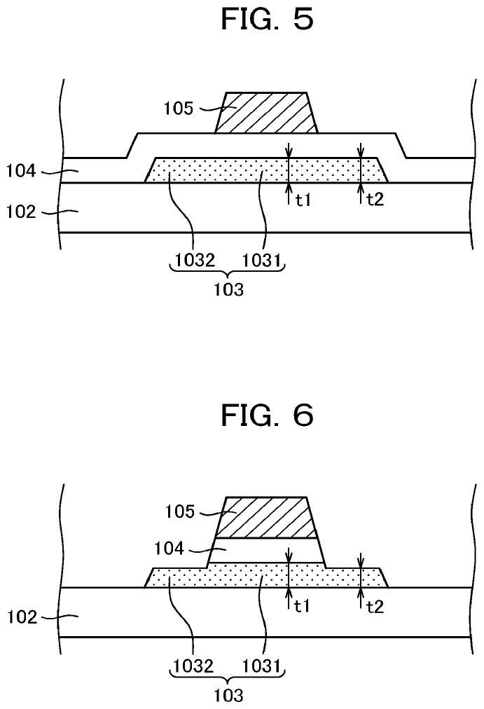

FIG. 5 is a cross sectional view of the conventional oxide semiconductor TFT. In FIG. 5, the gate insulating film 104 is formed covering the oxide semiconductor 103. This structure is the same as the structures of FIG. 3 and FIG. 4. In FIG. 5, a thickness t1 of the channel region 1031 of the oxide semiconductor 103 is the same as a thickness t2 of the SD region 1032.

FIG. 6 is a cross sectional view of another conventional oxide semiconductor TFT. In FIG. 6, the gate insulating film 104 is formed only under the gate electrode 105. The region of the oxide semiconductor 103 that is not covered by the gate insulating film 104 is covered by the interlayer insulating film 106 as shown in FIG. 4 and so on. In FIG. 6, oxygen is supplied from the gate insulting film 104 to the channel region 1031.

The feature of FIG. 6 is that a thickness t1 of the channel region 1031 of the oxide semiconductor 103 is thicker than a thickness t2 of the SD region 1032. The reason is that the surface of the oxide semiconductor 103 is simultaneously etched when the gate insulating film 104 is etched using the gate electrode 105 as the mask.

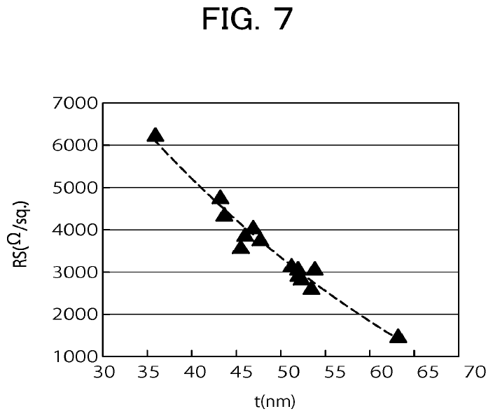

FIG. 7 is a graph that shows a relation between a thickness t of the oxide semiconductor 103 of IGZO and a sheet resistance RS. In FIG. 7, Boron (B) is dozed in a density of 3×10¹⁵/cm² by e.g. ion implantation. The ordinate of FIG. 7 is a sheet resistance (Q/sq), the abscissa is a thickness (nm) of the oxide semiconductor 103.

In FIG. 7, a sheet resistance RS decreases drastically with an increase in a thickness t of the oxide semiconductor 103. If the resistivity of the oxide semiconductor 103 is constant, the sheet resistance RS is inverse proportional to a film thickness t; however, the sheet resistance RS decreases more rapidly than inverse proportional in FIG. 7. This is supposed as that an influence of oxide increases according to a decrease in a thickness of the oxide semiconductor 103, consequently, resistivity of the oxide semiconductor 103 becomes larger.

It is necessary to decrease a thickness of the channel region 1031 in the oxide semiconductor TFT to decrease the leak current (OFF current). On the other hand, the resistance of the SD region 1032 in the oxide semiconductor TFT is preferable to be low. Namely, a large ON current is preferable; however, the ON current is controlled by a resistance of the SD region 1032.

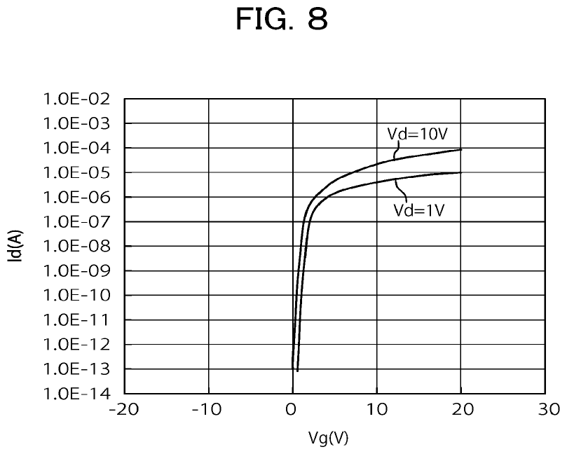

FIG. 8 is a graph that shows a relation between a gate voltage and a drain current of the oxide semiconductor when the resistance of the SD region 1032 is relatively low. In FIG. 8, the abscissa is a gate voltage Vg (V) and the ordinate is a drain current Id (A). The data are obtained when the drain voltage Vd is 1 V and 10 V. As shown in FIG. 8, the drain current Id increases even when the gate voltage Vg increases beyond 10 V. This means that the drain current Id can be increased with an increase in the gate voltage Vg, namely, ON current can be increased.

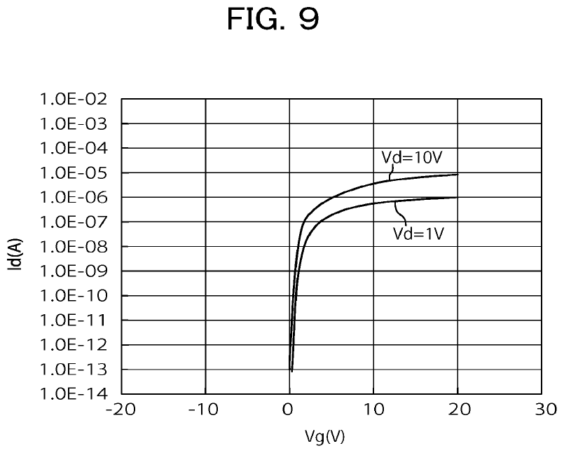

FIG. 9 is a graph that shows a relation between a gate voltage and a drain current of the oxide semiconductor when the resistance of the SD region 1032 is relatively high. In FIG. 9, the abscissa is a gate voltage Vg (V) and the ordinate is a drain current Id (A). The data are obtained when the drain voltage Vd is 1 V and 10 V. As shown in FIG. 9, the drain current Id saturates when the gate voltage Vg increases beyond 10 V. The drain current of FIG. 9 is lower compared with the drain current Id of FIG. 8 when the gate voltage Vg is 10 V; namely, ON current cannot be made high.

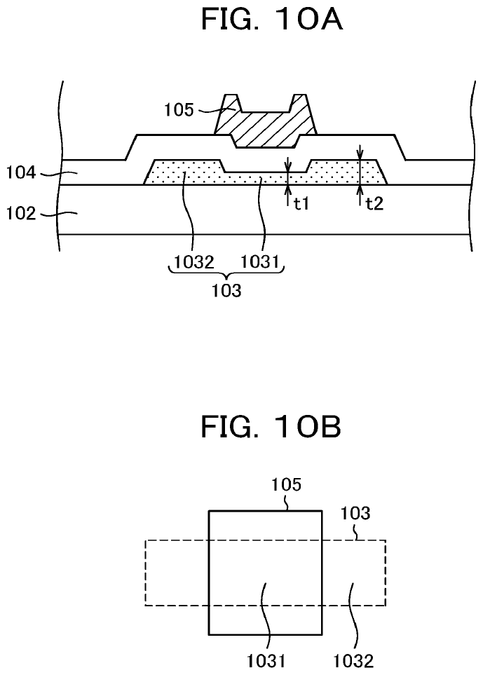

The present invention is based on the above explained inventor's research; the concrete embodiments are explained as follows. FIG. 10A is a cross sectional view of the oxide semiconductor TFT according to embodiment 1. FIG. 10A is a top gate type oxide semiconductor TFT. FIG. 10A differs from FIG. 5 in that a thickness t2 of the SD region 1032 of the oxide semiconductor 103 is thicker than a thickness t1 of the channel region 1031.

A thickness t1 of the channel region 1031 is determined by intended OFF current. Considering the OFF current, a thickness t1 of the channel region 1031 is between 200 nm and 10 nm, preferably between 60 nm and 10 nm. On the other hand, a thickness t2 of the SD region 1032 of the oxide semiconductor 103 is made thicker than t1. The value of t2-t1 is preferably 10 nm or more. The thickness t1 is measured at the center of the channel region 1031; the thickness t2 is a thickest portion in the SD region 1032.

FIG. 10B is a plan view of FIG. 10A. The channel region 1031 of the oxide semiconductor 103 is covered by the gate electrode 105. In the oxide semiconductor 103, the thickness t1 of the portion 1031 which is covered by the gate electrode 105 is thinner than the thickness t2 of the portion 1132 which is not covered by the gate electrode 105.

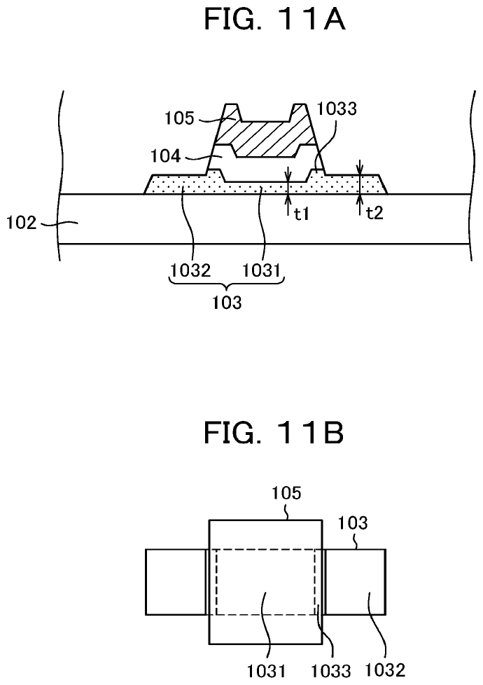

FIG. 11A is a cross sectional view of another example of the oxide semiconductor TFT according to embodiment 1. FIG. 11A differs from FIG. 6 in that a thickness t2 of the SD region 1032 of the oxide semiconductor 103 is thicker than a thickness t1 of the channel region 1031. A thickness t1 of the channel region 1031 is between 200 and 10 nm, preferably between 60 and 10 nm. On the other hand, a thickness t2 of the SD region 1032 of the oxide semiconductor 103 is made thicker than t1. The value of t2−t1 is preferably 10 nm or more.

The thickness t1 is measured at the center of the channel region 1031; the thickness t2 is a thickest portion in the SD region 1032. However, the projected portion 1033 of the oxide semiconductor 103, depicted in FIG. 11A, corresponding to the edge of the gate electrode 105 is not suitable for measuring thickness t2 of the SD region and the thickness t1 of the channel region.

FIG. 11B is a plan view of FIG. 11A. FIG. 11B is the same as FIG. 10B except the projected portions 1033 are visible at both sides of the channel region 1031 in FIG. 11B.

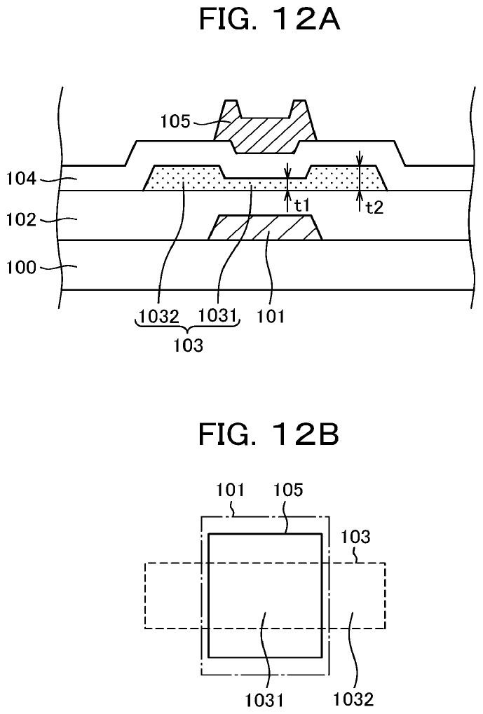

FIG. 12A is an example in which the light shading film 101 is provided beneath the oxide semiconductor 103 via the undercoat film 102 in the structure of FIG. 10A. The effect of the light shading film 101 is the same as explained in FIG. 3. In the meantime, a shield effect against a charge up of the TFT substrate 100 can be attained when a certain voltage, such as the common voltage, is applied to the light shading film 101. On the other hand, if a gate voltage is applied to the light shading film 101, the light shading film 101 can work as a gate electrode; in this case the TFT becomes dual gate type.

FIG. 12B is a plan view of FIG. 12A. FIG. 12B differs from FIG. 10B in that the light shading film 101 is formed beneath the oxide semiconductor 103. The light shading film 101 is made larger than the gate electrode 105 in a plan view; the light shading film 101 covers the channel 1031 of the oxide semiconductor film 103, which is formed beneath the gate electrode 105, from the bottom.

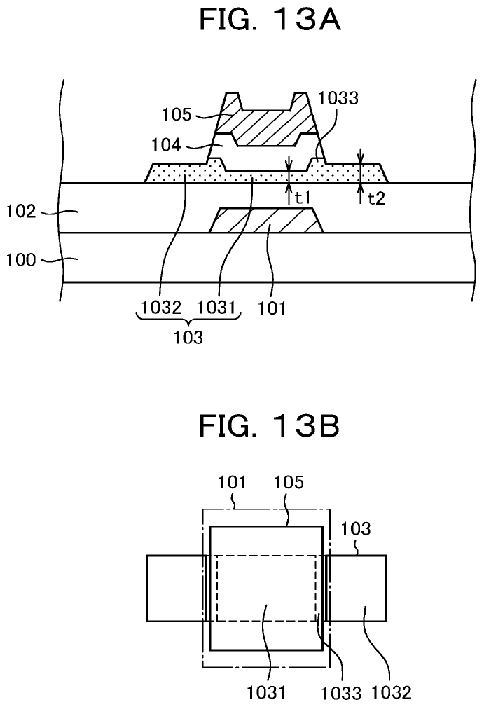

FIG. 13A is an example in which the light shading film 101 is provided beneath the oxide semiconductor 103 via the undercoat film 102 in the structure of FIG. 11A. The effect of the light shading film 101 is the same as explained in FIG. 3. In the meantime, a shield effect against a charge up of the TFT substrate 100 can be attained when a certain voltage as the common voltage is applied to the light shading film 101. On the other hand, if a gate voltage is applied to the light shading film 101, the light shading film can work as a gate electrode; in this case the TFT becomes dual gate type.

FIG. 13B is a plan view of FIG. 13A. FIG. 13B is the same as FIG. 12B except the projected portions 1033 are visible at both sides of the channel region 1031 of the oxide semiconductor 103.

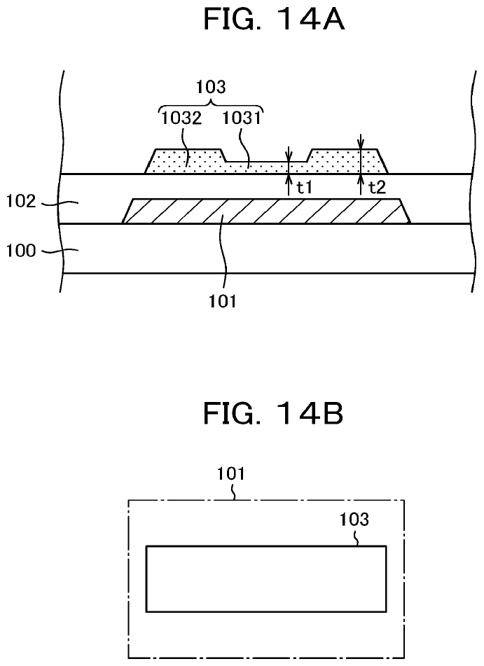

FIG. 14A is a plan view in which the present invention is applied to the bottom gate type oxide semiconductor TFT. In FIG. 14A, the light shading film 101 is formed on the TFT substrate 100; a gate voltage is applied to the light shading film 101 so that the light shading film 101 works as a bottom gate electrode. FIG. 14A differs from FIG. 12A in that the area of the light shading film 101, which works as the bottom gate electrode, is larger in FIG. 14A.

FIG. 14B is a plan view of FIG. 14A. In FIG. 14B, the light shading film (bottom gate electrode) 101 is larger both in lateral direction and longitudinal direction than the oxide semiconductor 103. Namely, the light shading film (bottom gate electrode) 101 covers the oxide semiconductor 102 completely from the bottom. By the way, it looks that the whole semiconductor 103 is influenced by light shading film (the gate electrode) 101 in FIG. 14A, however, actually, a resistance of the SD region 1032 is made low by ion doping by ion implantation or by contacting a metal, thus, the channel region 1031 and the SD region 1032 exist even in the oxide semiconductor 103 in FIG. 14A.

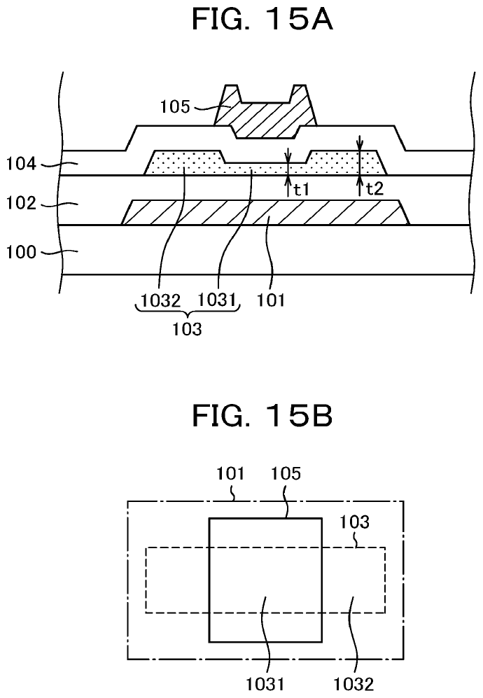

FIG. 15A is an example in which the present invention is applied to the dual gate type oxide semiconductor TFT. FIG. 15A differs from FIG. 14A in that the top gate electrode 105 is formed on the oxide semiconductor 103 via the gate insulating film 104. Adding the gate insulating film 104 and the gate electrode 105 to the structure of FIG. 14A, the TFT of FIG. 14A can work as the dual gate type TFT.

FIG. 15B is a plan view of FIG. 15A. FIG. 15B differs from FIG. 14B in that the top gate electrode 105 is formed on the oxide semiconductor 103. In FIG. 15B, the oxide semiconductor 103 is formed under the gate electrode 105, thus, the oxide semiconductor 103 is depicted by dotted lines. In FIG. 15B, the oxide semiconductor 103 and the top gate 105 are completely covered by the light shading film (bottom gate electrode) 101 from the bottom.

### Embodiment 2

Embodiment 2 discloses a manufacturing process to form the oxide semiconductor TFT explained in embodiment 1 in which a thickness t2 of the SD region 1032 is thicker than a thickness t1 of the channel region 1031.

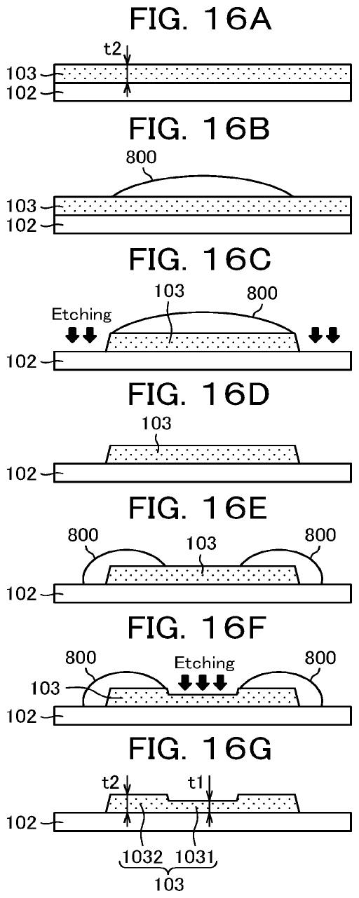

FIGS. 16A through 16G are cross sectional views that show a first process. FIG. 16A is a cross sectional view in which the oxide semiconductor 103 is formed on the undercoat film 102. The oxide semiconductor 103 is formed e.g. with sputtering. A thickness of the oxide semiconductor 103 of FIG. 16A is thicker than a thickness of the channel region 1031 of the final oxide semiconductor film 103.

FIG. 16B is an example in which the resist 800 is formed for patterning the oxide semiconductor 103. FIG. 16C is an example in which the oxide semiconductor film 103 is being eliminated by etching except the area that is covered by the resist 800. The oxide semiconductor 103 can be eliminated by dry etching of chloride gas base or wet etching of oxalic acid base. FIG. 16D is an example in which the resist 800 is eliminated after the oxide semiconductor 103 is etched.

FIG. 16E is a cross sectional view in which the resist 800 is formed on the SD region 1032 to make a thickness of the channel region 1031 thinner. FIG. 16F is a cross sectional view in which a thickness of the channel region 1031 is being made thinner by etching. The etching can be conducted through chloride gas base dry etching or oxalic acid base wet etching.

FIG. 16G is a cross sectional view in which the resist 800 is eliminated after a thickness of the channel region 1031 is made thinner by etching. Added processes, in the first process of FIGS. 16A through 16G, is not much; however, since the thickness of the oxide semiconductor 103 is controlled by etching, it is necessary to take care so that the thickness distribution in the plane of the channel region 1031 is not deteriorated. In addition, an influence of etching to the channel region 1031 of the oxide semiconductor 103 must be watched.

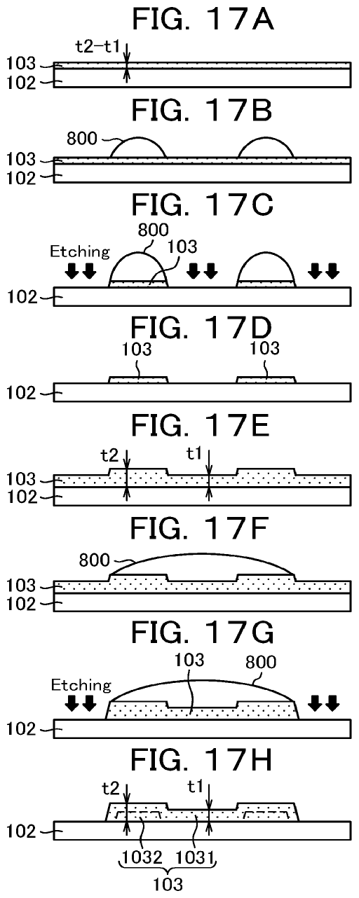

FIGS. 17A through 17H are cross sectional views that show a second process. The oxide semiconductor 103 is formed by two steps in the second process. FIG. 17A is a cross sectional view in which the oxide semiconductor 103 is formed on the undercoat film 102. A thickness of the oxide semiconductor 103 in this step is (t2-t1); where t2 is a thickness of the SD region 1032 and t1 is a thickness of the channel region 1031 in the final oxide semiconductor 103.

FIG. 17B is a cross sectional view in which the resist 800 is formed on the SD region 1032 of the oxide semiconductor 103 so that the oxide semiconductor 103 remains only at the SD region 1032. FIG. 17C is a cross sectional view in which the oxide semiconductor 103 is being eliminated by etching except the SD region 1032 where the resist 800 is coated. The etching can be conducted through chloride gas base dry etching or oxalic acid base wet etching. FIG. 17D is a cross sectional view in which the resist 800 is eliminated.

FIG. 17E is a cross sectional view in which the second oxide semiconductor 103 is formed by second step. A thickness of the oxide semiconductor 103 formed in the second step is the same as a thickness t1 of the channel region 1031. Consequently, a thickness of the oxide semiconductor 103 in the SD region 1032 becomes t2. FIG. 17F is a cross sectional view in which the resist 800 is formed to cover the channel region 1031 and the SD region 1032.

FIG. 17G is a cross sectional view in which the whole oxide semiconductor 103 is patterned by etching. FIG. 17H is a cross sectional view in which the resist 800 is eliminated. Thus, the oxide semiconductor 103 in which a thickness of the channel region 1031 is t1 and a thickness of the SD region 1032 is t2 is formed. The SD region 1032 of FIG. 17H is a two layer structure of the oxide semiconductor formed by the first step and the oxide semiconductor formed by the second step. The broken lines depict this two layer structure.

The second process needs more additional processes compared with the conventional process; however, since half etching of the channel region 1031 does not exist, deviations in the thickness in a plane of the channel region 1031 can be suppressed, and further, a damage to the channel region 1031 by etching can be avoided. Since the SD region 1032 of the oxide semiconductor 103 is a two layer structure, the structure of the oxide semiconductor 103 can be optimized by controlling the material and film forming condition for each of the first layer and the second layer. For example, ON current can be further increased by using the oxide semiconductor 103 of low resistivity for the oxide semiconductor 103 of the first step or controlling the depositing condition of the oxide semiconductor 103 in the first step so that the resistivity of the oxide semiconductor 103 is made low.

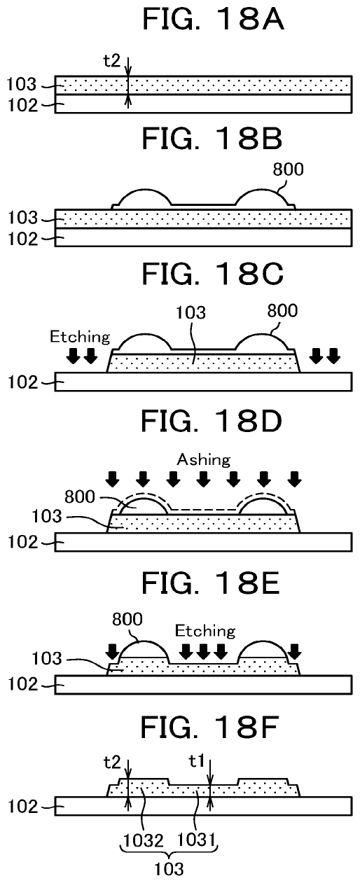

FIGS. 18A through 18F are cross sectional views of third process. FIG. 18A is a cross sectional view in which the oxide semiconductor 103 is formed on the undercoat film 102. A thickness of the oxide semiconductor 103 in FIG. 18A is thicker than a thickness of the channel region 1031 of the final oxide semiconductor 103. FIG. 18B is a cross sectional view in which the resist 800 is formed for the patterning of the oxide semiconductor 103. In FIG. 18B, a thickness of the resist 800 at the SD region 1032 of the oxide semiconductor 103 is made thicker than the resist 800 at other regions by using half tone exposure and so on.

FIG. 18C is a cross sectional view in which whole oxide semiconductor 103 is patterned by etching. FIG. 18D is a cross sectional view in which the resist 800 is being trimmed by e.g. oxygen plasma ashing. The resist 800 is removed from the surface of the oxide semiconductor 103 except the SD region 1032.

FIG. 18E is a cross sectional view in which the oxide semiconductor 103 is being made thin by etching except the SD region 1032. FIG. 18F is a cross sectional view in which the resist 800 is removed. As a result, the oxide semiconductor 103 is formed in which a thickness of the channel region 1031 is t1 while the SD region 1032 maintains a thickness of t2.

The added processes are the least in the third process; however, since the thickness of the oxide semiconductor 103 is controlled by etching, it is necessary to take care so that the thickness distribution in the plane of the channel region 1031 is not deteriorated. In addition, an influence of etching to characteristics of the channel region 1031 of the oxide semiconductor 103 must be watched. Further, technologies of half tone exposure to the resist 800 and trimming the resist 800 by plasma ashing are adopted; thus, careful controlling of the manufacturing condition in those processes must be taken.

### Embodiment 3

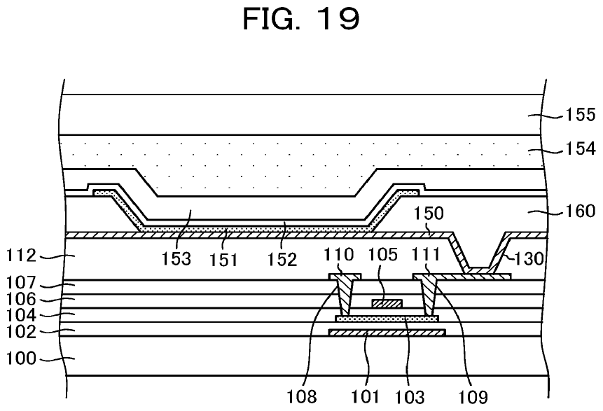

Embodiment 1 and embodiment 2 explain the case that the present invention is applied to the liquid crystal display device. The present invention can be applied not only to the liquid crystal display device but also to the organic EL (electroluminescent) display device. FIG. 19 is a cross sectional view of the display area of the organic EL display device. The structure of FIG. 19 is the same as the liquid crystal display device shown in FIG. 3 up to the process that: forming the oxide semiconductor TFT, covering the TFT by the organic passivation film 112, and forming the through hole 130 in the organic passivation film 112 to connect the TFT and the lower electrode 150.

In FIG. 19, the lower electrode 150, which works as an anode, is formed on the organic passivation film 112. The bank 160 having a hole is formed on the lower electrode 150. The organic EL layer 151 as the light emitting layer is formed in the hole of the bank 160. The upper electrode 152, which works as a cathode, is formed on the organic EL layer 151. The upper electrode 152 is formed in common to each of the pixels. The protecting film 153, including SiN film and so forth, is formed on the upper electrode 152. The circularly polarizing plate 155 is adhered to the protecting film 153 through the adhesive 154.

As shown in FIG. 19, the structure of the organic EL display device has the same structure as the liquid crystal display device explained in embodiment 1 up to: forming the drain electrode 110 for the oxide semiconductor TFT, the source electrode 111, and the organic passivation film 112. Therefore, the present invention is applicable to the organic EL display device.

### Embodiment 4

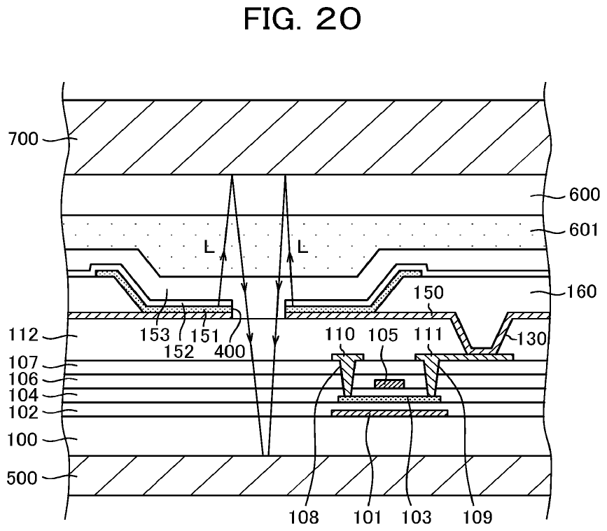

The present invention can be applied not only to the display devices but also to various semiconductor devices such as the sensor devices and so forth. FIG. 20 is an example in which the same structure as the organic EL display device is used as the photo sensor; namely, the organic EL display device is used as the light emitting elements. In FIG. 20, the light receiving element 500 is set under the TFT substrate 100 of the display area of the organic EL display device (used as a light emitting element) explained in FIG. 19. The face plate 600 formed from a transparent glass substrate or a transparent resin substrate is set at the top of the light emitting element through adhesive 601. An object 700 to be measured is disposed on the face plate 600.

In the light emitting element, the light emitting area is composed from the organic EL layer 151, the lower electrode 150, and the upper electrode 152. The window 400, in which the organic EL layer 151, the lower electrode 150, and the upper electrode 152 do not exist, is formed at the center of the light emitting element; light can pass through the window 400. In the meantime, a reflection electrode is formed under the lower electrode 150, thus, the light L emitted from the organic EL layer 151 is directed to upper direction.

In FIG. 20, the light L emitted from the organic EL layer 151 reflects at the object 700, goes through the window 400, and is received by the light receiving element 500, which is set under the TFT substrate 100; thus, an existence of the object 700 is measured. If the object 700 does not exist, the reflected light does not exist; therefore, current is not generated in the light receiving element 500. Thus, it is measurable whether the object 700 exists or not.

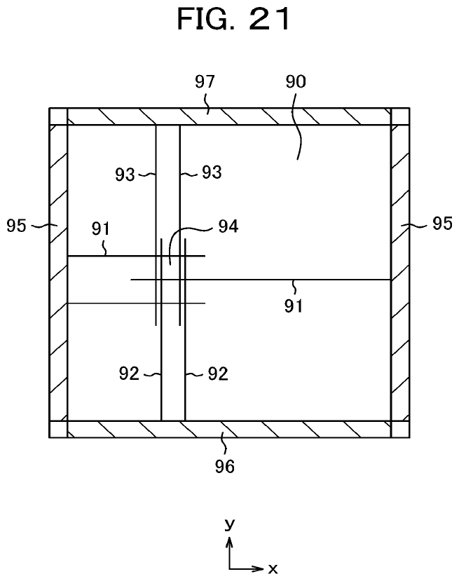

FIG. 21 is a plan view of the photo sensor in which the photo sensor elements shown in FIG. 20 are set in matrix. In FIG. 21, the scan lines 91 extend in lateral direction (x direction) from the scan line driving circuit 95 arranged on each side of the display area 90. The signal lines 92 extend in longitudinal direction (y direction) from the signal line driving circuit 96, which is located at the lower side of the display area 90; the power lines 93 extend in lower direction (-y direction) from the power circuit 97, which is located at the upper side of the display area 90. The sensor element 94 is in an area surrounded by the scan lines 91 and the signal lines 92 or surrounded by the scan lines 91 and the power lines 93.

In FIG. 21, the polysilicon TFTs can be used in the scan line driving circuit 95 and in the signal line driving circuit 96 and so forth; the oxide semiconductor TFTs can be used as the switching TFTs in sensor elements 94. Therefore, the oxide semiconductor TFTs explained in embodiment 1 and embodiment 2 can be used in such photo sensors.

In the meantime, the photo sensor of the present embodiment can detect two dimensional images by detecting the intensity of the reflection from the object 700, not only the existence of the object 700. Further, color images and spectral images can be detected by sensing for necessary color spectrum. Definition of the sensor is determined by a size of the sensor element 94 in FIG. 21; however, the definition can be controlled by summarizing several sensor elements 94 as one large sensor element.

The similar structure of the organic EL display device is applied to the photo sensor in FIGS. 20 and 21; the present invention can be applied not only to such a photo sensor but also can be applied to other types of the photo sensor. Further, the present invention can be applied not only to the photo sensor but also can be applied to other sensors like capacitance sensors and so forth, which use semiconductor circuit substrates.

What is claimed is:

1. A display device comprising:
a substrate; and
a thin film transistor formed on the substrate and having an oxide semiconductor,
wherein the thin film transistor has a source region, a drain region, and a channel region,
a thickness of the source region is thicker than a thickness of the channel region,
a thickness of the drain region is thicker than a thickness of the channel region,
the channel region has a first projection at a portion contacting the source region, and a second projection at a portion contacting the source region,
a thickness of the first projection is thicker than a thickness of the center of the channel region, than a thickness of the source region, and, than a thickness of the drain region, and
a thickness of the second projection is thicker than a thickness of the center of the channel region, than a thickness of the source region, and, than a thickness of the drain region.

2. The display device according to claim 1,
wherein, a thickest portion of the source region and a thickest portion of the drain region is thicker than a thickness at the center of the channel region by 10 nm or more.

3. The display device according to claim 1,
wherein, a thickness of the channel region is 200 nm or less and 10 nm or more at the center of the channel region.

4. The display device according to claim 1,
wherein, a thickness of the channel region is 60 nm or less and 10 nm or more at the center of the channel region.

5. The display device according to claim 1,
wherein the source region and the drain region have a two layer structure and the channel region has a one layer structure.

6. The display device according to claim 1,
wherein the source region and the drain region have a two layer structure comprising a first layer and a second layer, the first layer is between the second layer and the substrate, and
a resistivity of the first layer is lower than a resistivity of the second layer.

7. The display device according to claim 1,
wherein, the thin film transistor has a gate electrode which overlaps with a part of the oxide semiconductor in a plan view, and a gate insulating film which is between the part of the oxide semiconductor and the gate electrode, and
the oxide semiconductor has a region that does not overlap with the gate insulating film in a plan view.

8. A display device comprising:
a substrate; and
a thin film transistor formed on the substrate and having an oxide semiconductor and a gate electrode,
wherein the oxide semiconductor has a first region which overlaps with the gate electrode in a plan view, and a second region which does not overlap with the gate electrode in a plan view,
a thickness of a part of the first region is thinner than a thickness of the second region,
the first region has a projection at a portion contacting the second region,
a thickness of the projection is thicker than a thickness of the center of the first region, and
a thickness of the projection is thicker than a thickness of the second region.

9. The display device according to claim 8,
wherein, the oxide semiconductor has a channel region, a source region and a drain region, and
a thickness of a part of the channel region is thinner than a thickness of the source region and the drain region.

10. A semiconductor device comprising:
a substrate; and
a sensor element formed on the substrate,
wherein the sensor element including a thin film transistor having an oxide semiconductor,
the thin film transistor has a source region, a drain region, and a channel region,
a thickness of a part of the channel region is thinner than a thickness of the source region and, than the drain region, the channel region has a first projection at a portion contacting the source region, and a second projection at a portion contacting the source region,
a thickness of the first projection is thicker than a thickness of the center of the channel region, than a thickness of the source region, and, than a thickness of the drain region, and
a thickness of the second projection is thicker than a thickness of the center of the channel region, than a thickness of the source region, and, than a thickness of the drain region.

11. The display device according to claim 10,
wherein, a thickest portion of the source region and a thickest portion of the drain region is thicker than a thickness at the center of the channel region by 10 nm or more.

12. The display device according to claim 10,
wherein, a thickness of the channel region is 60 nm or less and 10 nm or more at the center of the channel region.

13. The display device according to claim 10,
wherein the source region and the drain region have a two layer structure comprising a first layer and a second layer, the first layer is between the second layer and the substrate, and
a resistivity of the first layer is lower than a resistivity of the second layer.

14. The display device according to claim 10,
wherein, the thin film transistor has a gate electrode which overlaps with a part of the oxide semiconductor in a plan view, and a gate insulating film which is between the part of the oxide semiconductor and the gate electrode, and
the oxide semiconductor has a region that does not overlap with the gate insulating film in a plan view.
